(19) United States
(12) Patent Application Publication
(10) Pub. No.: US 2008/0062665 A1
(43) Pub. Date: Mar. 13, 2008

(54) MOUNTING STRUCTURE

(76) Inventors: TETSUYA NAKATSUKA, Fujisawa (JP); Koji Serizawa, Fujisawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/829,301

(22) Filed: Jul. 27, 2007

(30) Foreign Application Priority Data
Sep. 12, 2006 (JP) JP 2006-246255

(51) Int. Cl. H05K 7/02

(52) U.S. Cl. 361/768

(57) ABSTRACT

There is proposed a mounting structure including a plurality of components each having a plurality of solder bumps, a substrate having a plurality of lands, and a solder connecting portion for connecting the solder bump and the land, wherein the land provided in an outer peripheral portion of the substrate is smaller than that of the land in a central portion of the substrate.

### CROSS REFERENCES TO RELATED APPLICATION

The present application claims priority from Japanese application JP 2006-246255 filed on Sep. 12, 2006, the content of which is hereby incorporated by reference into this application.

### BACKGROUND OF THE INVENTION

1. Field of the Invention

The present invention relates to a mixed mounting method using a Pb-free solder alloy with less toxicity and a soldering apparatus therefor, as well as a mounting structure using this. The Pb-free solder alloy can be applied to bonding of an electronic component to a substrate such as an organic substrate, and is an alternative to Sn-37Pb (unit: mass %) solder used for soldering at about 220° C.

2. Description of Related Art

A conventional soldering method to a substrate such as an organic substrate in an electric product is constituted by a reflow soldering step in which hot air is blown to the substrate to melt a solder paste printed on an electrode to solder a surface mounting component, and a flow soldering step in which a jet of the molten solder is brought into contact with the substrate to solder a part of surface mounting components such as an insertion mounting component and a chip component.

This soldering method is called a mixed mounting method. Incidentally, there arises a demand for use of a Pb-free solder alloy with less toxicity, with respect to the solder paste used in the reflow soldering step, and the jet of the molten solder used in the flow soldering step in the mixed mounting method.

As conventional arts relating to the mounting method using the Pb-free solder, the following six patent documents are known.

JP-A-10-166178 discloses a Sn—Ag—Bi system or Sn—Ag—Bi—Cu system solder alloy as Pb-free solder. JP-A-11-179586 discloses that Sn—Ag—Bi system solder which is dominant as Pb-free solder is connected with an electrode of which a surface a Sn—Bi system layer is applied to. JP-A-11-221694 discloses that electronic components are mounted by the reflow soldering onto both surfaces consisting of a first surface and a second surface of an organic substrate using Pb-free solder containing Sn as a main component, but containing 0 to 65 mass % of Bi, 0.5 to 4.0 mass % of Ag, and 0 to 3.0 mass % in total of Cu or/and In. JP-A-11-354919 discloses that in a method of connecting an electronic component and a substrate using Pb-free solder containing Bi, the solder is cooled at a cooling rate of about 10 to 20° C./s. JP-A-2001-168519 discloses that in a method of performing surface connection mounting of an electronic component onto an A-side surface of a substrate by the reflow soldering, and then performing connection mounting of a lead of the electronic component inserted from the A-side surface to an electrode by the flow soldering on a B-side surface of the substrate, the solder used for the reflow soldering on the A-side surface is Pb-free solder constituted with a composition of Sn-(1.5 to 3.5 wt %)Ag-(0.2 to 0.8 wt %)Cu-(0 to 4 wt %)In-(0 to 2 wt %)Bi, and the solder used for the flow soldering on the B-side surface is Pb-free solder constituted with a composition of Sn-(0 to 3.5 wt %)Ag-(0.2 to 0.8 wt %)Cu. JP-A-2001-36233 discloses that on the occasion of performing flow soldering using Pb-free solder having an eutectic composition with higher melting point than the conventional Sn-37Pb, a heat conducting material is provided between a component main body and a substrate to prevent the temperature difference between an organic substrate and an electronic component main body from becoming large at the time of cooling the substrate after the soldering.

### BRIEF SUMMARY OF THE INVENTION

However, the following problems are not considered in any of the above described prior arts.

The problems occur in the case where all solder bumps on a low heat resistant surface mounting component side for performing bump connection are formed from Sn-3Ag-0.5Cu solder because the Sn-3Ag-0.5Cu solder which is representative of Pb-free solder has high connection reliability (in a temperature cycle test under the conditions of −55° C. to 125° C., 1 cycle/h), and a solder paste for reflow connection is formed from Sn-9Zn and Sn-8Zn-3Bi with the melting points of about 200° C.

The first problem is that since a component in an outer peripheral portion is warped when performing reflow connection, the connection is sometimes hindered due to flux which stays between a molten paste and a solder bump even if the solder paste completely melts in the outer peripheral portion. This would be because the component does not sufficiently sink due to surface tension of the staying flux. On the other hand, when the warp of the substrate disappears after the reflow, the solder wets and spreads on a bump side surface excessively, and as a result thereof, a portion which is connected while partially lacking solder is formed in the connected portion, so that the connection strength may be reduced.

The second problem is that, while Sn—Zn system solder is available for reflow soldering at a low temperature using lead-free solder, Zn is an element which is easily oxidized by oxygen in the atmosphere during soldering, and therefore, its wettability is unfavorable with respect to an electrode and a solder bump to be soldered, so that the connection strength at an interface between the solder and the member to be connected becomes low as compared with the case of another solder such as Sn—Ag solder.

The present invention is made to solve the above described problems and provide the following methods to solve the respective problems.

First, in order to solve the above first problem, the present invention proposes to make an upper end of a molten solder paste near an outer peripheral portion higher than an upper end of a molten solder paste near a central portion by a warp amount of a component occurring in the outer peripheral portion at the time of performing reflow connection. Further, the present invention also proposes to form a wetting and spreading inhibition region on a bump, as a means for preventing the solder from excessively wetting and spreading on a bump side surface. As concrete means thereof, the followings are cited.

That is, the means are (1) a means of making a land size (or an opening size of a solder resist formed on the land) near an outer peripheral portion smaller than a land size (or an opening size of the solder resist formed on the land) near a central portion in a substrate to which a component is connected, (2) a means of coating a side surface of a solder bump near an outer peripheral portion of a low heat resistant mounting component with a material such as a solder resist which inhibits solder wetting, (3) a means of making the outer peripheral length of a land on a substrate side near an outer peripheral portion about 3.7 times larger than a land size, and (4) a means of increasing a solder paste supply amount to a substrate side for connection with a solder bump near an outer peripheral portion by about 10 to 50%.

Next, in order to solve the above second problem, it is necessary to use solder with a possibly low content amount of Zn in a place where relatively high stress occurs and connection strength is required.

Concretely, a solder bump before being connected mainly includes a Sn—Zn system, and its composition of the bump near a central portion includes Zn with a content amount of 7 to 9 mass % and the rest of Sn, whereas the composition of the bump near an outer peripheral portion includes Zn with a content amount of 4 to 7 mass % and the rest of Sn.

The reason is that the solder with the Zn content amount of 7 to 9 mass % is capable of reflow soldering at 210 to 215° C., and the solder with the Zn content amount of 4 to 7 mass % is capable of reflow soldering at 215 to 220° C. Accordingly, by using the former near the central portion, and the latter near the outer peripheral portion, the reflow soldering can be carried out while protecting a surface mounting component with the heat resistant temperature of 220° C.

Next, the means for solving the first problem will be described in detail.

First, according to the above means (1), the size of a land 4b near the outer peripheral portion of a substrate 2 (FIG. 1B) is reduced with respect to the size of a land 4a in the central portion of the substrate 2 (FIG. 1A), in the substrate 2 with which a component 1 having a bump 3 is connected. In this case, a solder paste supplied onto the land 4b near the outer peripheral portion cannot stay on a land surface after being melted due to the small land size, so that the molten solder paste spreads to a higher position. Therefore, sufficient connection becomes possible even to the solder bump of a component which warps near the outer peripheral portion. In this case, since the warp of the substrate disappears to return to an original state after reflow, the state of the solder paste after being connected becomes that as shown in FIG. 1A, in which the height of a solder connecting portion 5b with respect to the substrate formed by the solder paste near the outer peripheral portion of the substrate is larger than the height of a solder connecting portion 5a with respect to the substrate formed by the solder paste in the central portion.

Next, the means (2) is a means of coating a side surface of the solder bump 3 near the outer peripheral portion with a material such as a solder resist 6 which inhibits solder wetting as shown in FIG. 2B, in order to solve the problem that the connection strength is reduced due to wetting and spreading of the solder to the side surface of the solder bump 3 of the component 1, by which a part of a solder connecting portion 5c becomes thin as shown in FIG. 2A. The supplied solder paste has no other choice but to wet a place of the bump lower portion where solder wetting is not inhibited, and cannot escape to the solder side surface. Therefore, it is possible to obtain a solder connecting portion 5d where a thin portion of the above problem is not formed.

Further, in the case of the means (3) where the outer peripheral length of the land on the substrate side near the outer peripheral portion is formed to exceed the size about 3.14 times (circle ratio) as large as the land size (diameter) in the central portion, the land shape becomes a complicated shape significantly differing from a complete round, and when the outer peripheral length exceeds the size about 3.7 times as large as the land size, the solder paste supplied onto the land near the outer peripheral portion hardly wets the lands. Therefore, the solder cannot sufficiently stay on the substrate land surface after being melted, so that the height can be made larger than that in the central portion, as with the case of the method (1).

Consequently, according to this method, a solder paste in any place can be brought into contact with the solder bump of the component of which the outer peripheral portion warps at the time of reflow, after being melted.

Finally, in the case of the means (4) where the solder paste supply amount to the substrate side for connection with the solder bump near the outer peripheral portion is increased by substantially 10 to 50%, the effect similar to the above described (1) to (3) can be also obtained.

These and other objects, features and advantages of the invention will be apparent from the following more particular description of preferred embodiments of the invention, as illustrated in the accompanying drawings.

### BRIEF DESCRIPTION OF THE SEVERAL VIEWS OF THE DRAWINGS

FIG. 1A is a view showing a connecting portion of a low heat resistant mounting component and a substrate in a substrate central portion;

FIG. 1B is a view showing a connecting portion of the low heat resistant mounting component and the substrate in a substrate outer peripheral portion;

FIG. 2A is a view showing a connecting portion a land of the substrate and a normal bump of the component in the substrate outer peripheral portion;

FIG. 2B is a view showing a connecting portion of a land of the substrate and a bump partially coated with a solder resist of the component in the substrate outer peripheral portion; and

FIG. 3 shows the state in which notched portions are provided at four spots in a circular shape with a diameter of 0.5 mm in a substrate side land near the outer peripheral portion of the substrate to which the low heat resistant mounting component is connected, so that the outer peripheral length thereof is about 3.8 times as large as the land size.

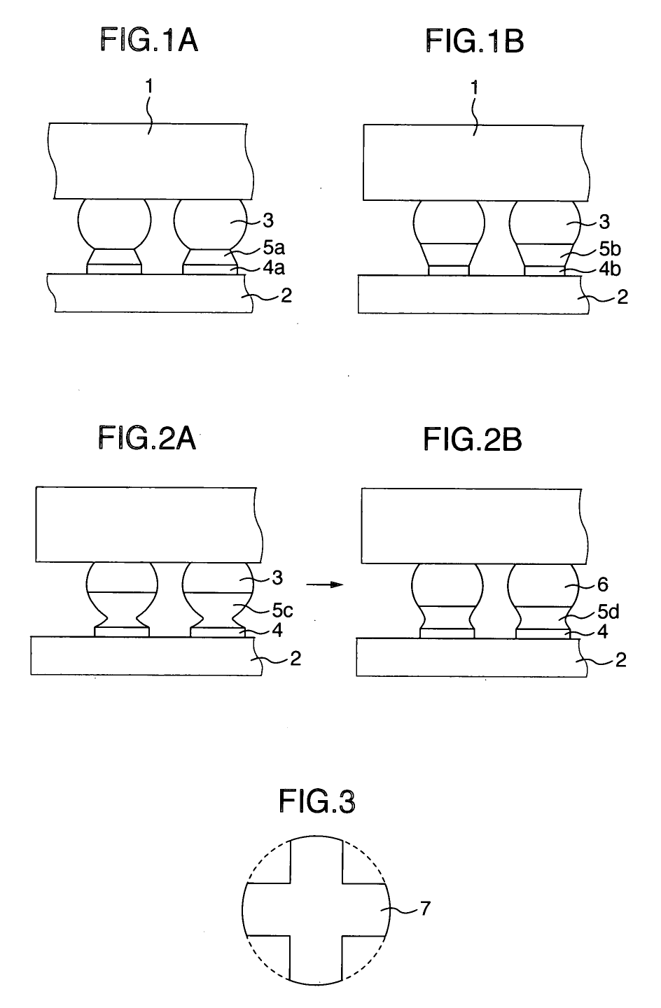

### DETAILED DESCRIPTION OF THE INVENTION

Embodiments of the present invention will be described in detail.

### Embodiment 1

A full grid BGA which is a low heat resistant component (the heat resistant temperature: 220° C., the component size: 23 mm×23 mm, the bump pitch: 1.0 mm, the number of bumps: 484 (22 rows×22 columns), the bump composition: Sn-9Zn) is mounted on a substrate on which a Sn-9Zn solder paste (the supply thickness: 0.15 mm, the supply diameter: 0.5 mm) has been printed, and then reflow soldering is performed so that the peak temperature of the bumps in the center of the component becomes 220° C.

The following two kinds of substrates are used for the connection. In substrate B, the five columns on an outer side (340 bumps) are set as an outer peripheral portion, and the land size in this portion is made smaller than that in a central portion.

Therefore, the remaining portion, that is, a portion consisting of the 12 rows×12 columns (144 bumps) is called the central portion.

For the respective substrate samples, one BGA is connected to each substrate, and 100 substrates per each kind, namely, 200 substrates in total are produced.

### (Substrate A)

Land size in central portion (diameter): 0.5 mm Land size in outer peripheral portion (diameter): 0.5 mm

### (Substrate B)

### Land size in central portion (diameter): 0.5 mm

### Land size in corner portion (diameter): 0.4 mm

As a result thereof, connection errors between the bumps and paste molten portions occur in the ratio of 1% of substrates A, but no connection error occurs in substrates B.

As a result of carrying out a temperature cycle test (−55 to 125° C., 1 cycle/h) by selecting ten substrates in which the connection error does not occur from each sample, namely, selecting 20 substrates in total, it is confirmed that breakage in an interface between an electrode on the BGA side and the solder bump occurs in the corner portion in each of two substrates among ten substrates with respect to substrates A, at the time of about the 200^{th} cycle.

However, no breakage is found in substrates B even after the lapse of 500 cycles. Therefore, it is confirmed that the effects of prevention of the solder connection error and enhancement of connection reliability are obtained by the present method.

### Embodiment 2

The full grid BGA which is a low heat resistant component (the heat resistant temperature: 220° C., the component size: 23 mm×23 mm, the bump pitch: 1.0 mm, the number of bumps: 484 (22 rows×22 columns), the bump composition: Sn-9Zn) is mounted on the substrate on which the Sn-9Zn solder paste (the supply thickness: 0.15 mm, the supply diameter: 0.5 mm) has been printed, and then the reflow soldering is performed so that the peak temperature of the bumps in the center of the component becomes 220° C.

The following substrate, and components A and B are used for the connection.

### (Substrate)

### Land size in central portion (diameter): 0.5 mm

### Land size in outer peripheral portion (diameter): 0.5 mm

### (Component A)

No treatment is applied to the BGA.

### (Component B)

The five columns on an outer side of the BGA (340 bumps) are set as an outer peripheral portion, and a part of each bump surface in this portion is coated with a solder resist.

At this time, the solder resist is applied to a portion of about 60% in height on a component package side, and is not attached to a portion of about 40% in height on a side to be contacted with the paste. Therefore, the remaining portion consisting of 12 rows×12 columns (144 bumps) is called the central portion, and the bumps in this portion are not coated with the solder resist at all.

For the respective substrate samples, one BGA is connected to each substrate, and 100 substrates per each component, namely, 200 substrates in total are produced.

The substrates to which components A and B are connected will be called substrates A and B, respectively.

As a result thereof, connection errors between the bumps and paste molten portions occur in the ratio of 1% of substrates A, but no connection error occurs in substrates B.

As a result of carrying out the temperature cycle test (−55 to 125° C., 1 cycle/h) by selecting ten substrates in which the connection error does not occur from each sample, namely, selecting 20 substrates in total, it is confirmed that breakage in the interface of the electrode on the BGA side and the solder bump occurs in the corner portion in each of two substrates among ten substrates with respect to substrates A at the time of about the 200^{th} cycle.

However, no breakage is found in substrates B even after the lapse of 500 cycles. Therefore, it is confirmed that the effects of prevention of the solder connection error and enhancement of connection reliability are obtained by the present method.

### Embodiment 3

The full grid BGA which is a low heat resistant component (the heat resistant temperature: 220° C., the component size: 23 mm×23 mm, the bump pitch: 1.0 mm, the number of bumps: 484 (22 rows×22 columns), the bump composition: Sn-9Zn) is mounted on the substrate on which the Sn-9Zn solder paste (the supply thickness: 0.15 mm, the supply diameter: 0.5 mm) has been printed, and then the reflow soldering is performed so that the peak temperature of the bumps in the center of the component becomes 220° C.

The following two kinds of substrates are used for the connection. In substrate B, the five columns on the outer side (340 bumps) are set as an outer peripheral portion, and each substrate side land shape 7 in this portion is formed so that an outer peripheral length becomes about 3.8 times as large as the land size by providing notched portions at four spots in its circular shape with a diameter of 0.5 mm as shown in FIG. 3.

Meanwhile, the remaining portion, that is, the portion consisting of the 12 rows×12 columns (144 bumps) is called the central portion, and each land shape of this portion is remained the circular shape with a diameter of 0.5 mm.

For the respective substrate samples, one BGA is connected to each substrate, and 100 substrates per each kind, namely, 200 substrates in total are produced.

As a result thereof, connection errors between the bumps and paste molten portions occur in the ratio of 1% of substrates A, but no connection error occurs in substrates B.

As a result of carrying out the temperature cycle test (−55 to 125° C., 1 cycle/h) by selecting ten substrates in which the connection error does not occur from each sample, namely, selecting 20 substrates in total, it is confirmed that breakage in the interface of the electrode on the BGA side and the solder bump occurs in the corner portion in each of two substrates among ten substrates with respect to substrates A at the time of about the 200^{th} cycle.

However, no breakage is found in substrates B even after the lapse of 500 cycles. Therefore, it was confirmed that the effects of prevention of the solder connection error and enhancement of connection reliability are obtained by the present method.

### Embodiment 4

The full grid BGA which is a low heat resistant component (the heat resistant temperature: 220° C., the component size: 23 mm×23 mm, the bump pitch: 1.0 mm, the number of bumps: 484 (22 rows×22 columns), the bump composition: Sn-9Zn) is mounted on the substrate on which the Sn-9Zn solder paste (the supply thickness: 0.15 mm) has been printed, and then the reflow soldering is performed so that the peak temperature of the bumps in the center of the component becomes 220° C.

The following four kinds of substrates are used for the connection. In each of substrates B, C and D, the five columns on the outer side (340 bumps) are set as an outer peripheral portion, and the solder paste supply diameter in this portion is made larger than that of the remaining portion (which will be called the central portion) of the 12 rows×12 columns (144 bumps), so that a larger amount of solder paste is supplied thereon.

For the respective substrate samples, one BGA is connected to each substrate, and 50 substrates per each kind, namely, 200 substrates in total are produced.

### (Substrate A)

Solder paste supply diameter in central portion: 0.5 mm Solder paste supply diameter in outer peripheral portion: 0.5 mm

### (Substrate B)

Solder paste supply diameter in central portion: 0.5 mm
Solder paste supply diameter in outer peripheral portion: 0.53 mm

### (Substrate C)

Solder paste supply diameter in central portion: 0.5 mm
Solder paste supply diameter in outer peripheral portion: 0.6 mm

### (Substrate D)

Solder paste supply diameter in central portion: 0.5 mm
Solder paste supply diameter in outer peripheral portion: 0.65 mm

As a result thereof, connection errors between the bumps and paste molten portions occur in the ratio of 2% of substrates A, but no connection error occurs in substrates B, C and D.

However, in substrates D, solder bridges are generated between adjacent connecting portions in the ratio of 4%.

In substrates A, B, C and D, the solder paste supply amounts near the outer peripheral portions are made larger by 0%, about 12%, about 44% and about 69%, respectively, with respect to those near the inside.

As a result of carrying out the temperature cycle test (−55 to 125° C., 1 cycle/h) by selecting ten substrates in which the connection error and the solder bridges do not occur from each sample, namely, 40 substrates in total, it is confirmed that breakage in the interface of the electrode on the BGA side and the solder bump occurs in the corner portion in each of two substrates among ten substrates with respect to substrates A at the time of about the 200^{th} cycle.

However, no breakage is found in substrates B, C and D even after the lapse of 500 cycles. Therefore, it is confirmed that the effects of prevention of the solder connection error and enhancement of connection reliability are obtained by the present method.

### Embodiment 5

The full grid BGA which is a low heat resistant component (the heat resistant temperature: 220° C., the component size: 23 mm×23 mm, the bump pitch: 1.0 mm, the number of bumps: 484 (22 rows×22 columns)) is mounted on the substrate on which the Sn-9Zn solder paste (the supply thickness: 0.15 mm, the supply diameter: 0.5 mm) has been printed, and then the reflow soldering is performed so that the peak temperature of the bumps in the center of the component becomes 220° C. The following substrate is used for the connection.

In the substrate, the five columns on the outer side (340 bumps) are set as an outer peripheral portion, and each land size in this portion is made smaller than that in a central portion.

The remaining portion, that is, the portion consisting of the 12 rows×12 columns (144 bumps) is the central portion.

A component in which the solder bumps of Sn-9Znn are provided in the central portion, and the solder bumps of Sn-9Zn are also provided in the outer peripheral portion is referred to as component A.

Further, a component in which the solder bumps of Sn-9Zn are provided in the central portion, and the solder of Sn-4Zn with relatively less Zn content and high reliability is provided in the outer peripheral portion is referred to as component B.

For the respective substrate samples, one BGA is connected to each substrate, and 100 substrates per each component, namely, 200 substrates in total are produced.

### (Substrate Specifications)

### Land size in central portion (diameter): 0.5 mm

### Land size in corner portion (diameter): 0.4 mm

As a result thereof, no connection error between the bumps and paste molten portions occur with respect to both substrates A and B.

As a result of carrying out the temperature cycle test (−55 to 125° C., 1 cycle/h) by using ten substrates from each sample, namely, using 20 in total, it is confirmed that breakage in the interface between the electrode on the BGA side and the solder bump occurs in the corner portion in one substrate among ten substrates with respect to substrates A at the time of about the 700^{th} cycle.

However, no breakage is found in substrates B even after the lapse of 1000 cycles. Therefore, it is confirmed that the effects of prevention of the solder connection error and enhancement of connection reliability are obtained by the present method.

Several embodiments have been described taking a Sn—Zn solder paste as an example in the above, but the present invention is not limited to those, and needless to say, the effect can be obtained even if another solder paste is used as long as it is combined with the above described structures.

According to the present invention, by improving a supply form and a composition of a paste which is connected with a bump of a low heat resistant component for performing bump connection, it is possible to provide a method of performing reflow soldering of the component while thermally protecting the component and ensuring high connection reliability.

The invention may be embodied in other specific forms without departing from the spirit or essential characteristics thereof. The present embodiment is therefore to be considered in all respects as illustrative and not restrictive, the scope of the invention being indicated by the appended claims rather than by the foregoing description and all changes which come within the meaning and range of equivalency of the claims are therefore intended to be embraced therein.

1. A mounting structure comprising:
a plurality of components each having a plurality of solder bumps;
a substrate having a plurality of lands; and
a solder connecting portion which connects said solder bump and said land, wherein
the land provided in an outer peripheral portion of the substrate is smaller than that in a central portion of the substrate.

2. The mounting structure according to claim 1, wherein a solder resist is provided on a side surface of the solder bump connected with the land provided in the outer peripheral portion.

3. The mounting structure according to claim 1, wherein an outer peripheral length of the land provided in the outer peripheral portion is equal to or more than 3.7 times as large as a diameter of the circular land in the central portion.

4. The mounting structure according to claim 1, wherein the bump in the outer peripheral portion has a composition of 4 to 7 mass % of Zn and the rest of Sn, and the bump in the central portion has a composition of 7 to 9 mass % of Zn and the rest of Sn.
